(19) United States
(12) Patent Application Publication
(10) Pub. No.: US 2016/0093960 A1
(43) Pub. Date: Mar. 31, 2016

(54) Press-Fit Internal Cable

(71) Applicant: INTEL CORPORATION, SANTA CLARA, CA (US)

(72) Inventor: KUAN-YU CHEN, Portland, OR (US)

(73) Assignee: INTEL CORPORATION, SANTA CLARA, CA (US)

(21) Appl. No.: 14/498,790

(22) Filed: Sep. 26, 2014

(51) Int. Cl. H01R 9/20; H05K 1/11; H05K 7/10; G06F 1/16

(52) U.S. Cl. CPC H01R 9/20; G06F 1/16; G06F 1/1684; H05K 1/115; H05K 7/10

(57) ABSTRACT

A press-fit cable is described herein. The press-fit cable includes a plurality of cable wires and a plurality of pins. The plurality of pins is coupled with the plurality of cable wires. Additionally, the plurality of pins is to directly mate to a circuit board without a receptacle.

### TECHNICAL FIELD

This disclosure relates generally to an internal cable design. More specifically, a system is described in which internal cables include press-fit cables.

### BACKGROUND ART

Within a computing system, a number of cables may be routed inside the enclosure to connect various panels and devices to a printed circuit board of the system. Conventional cables include a plug with a header that is mated with a receptacle soldered onto a main printed circuit board, such as a motherboard. However, the receptacle and mating interface between plug and receptacle can cause an impedance mismatch as well as excessive crosstalk that may result in a degraded signal transfer.

### BRIEF DESCRIPTION OF THE DRAWINGS

FIG. 1 is a diagram of computing system including a press-fit area;

FIG. 2 is an illustration of a press-fit cable form factor;

FIG. 3 is an illustration of a press-fit cable connected to a motherboard;

FIG. 4 is an illustration of a press-fit cable with a protective press-fit head connected to a motherboard;

FIG. 5A is an illustration of a press-fit internal cable;

FIG. 5B is an illustration of a press-fit internal cable with an overmold;

FIG. 6 is an illustration of a vertical press-fit internal cable and a horizontal press-fit internal cable;

FIG. 7 is an illustration of a one end press-fit cable and a two end press-fit cable;

FIG. 8 is a process flow diagram of a method for receiving a press-fit cable at a circuit board;

FIG. 9A is a time domain reflectometer plot comparing impedance discontinuities;

FIG. 9B is a time domain transmission plot comparing a crosstalk response;

FIG. 10A is a voltage margin comparison for a traditional cable and a press-fit cable according to the present techniques;

FIG. 10B is a timing margin comparison for a traditional cable and a press-fit cable according to the present techniques;

FIG. 11 is a block diagram of components present in a computer system in accordance with an embodiment of the present techniques.

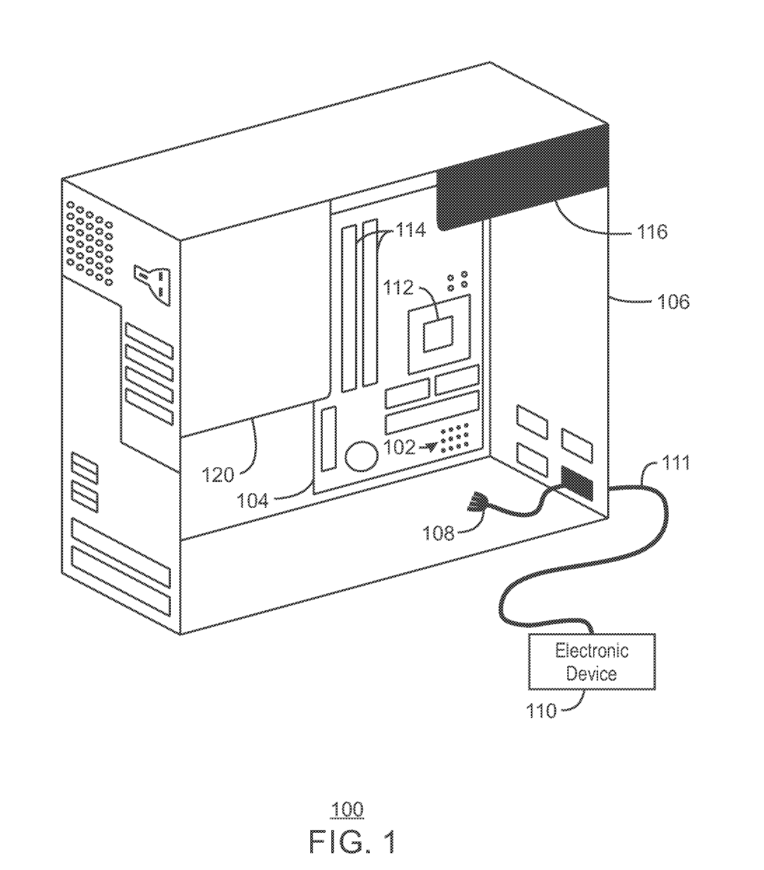

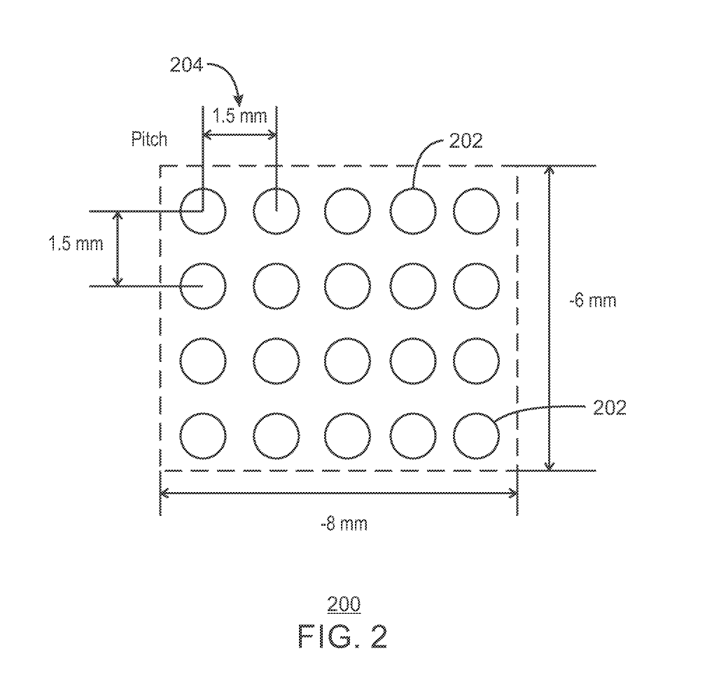

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

As discussed above, conventional cables include a plug that is mated of a receptacle on a printed circuit board (PCB). In some cases, the mating between the plug and the receptacle is responsible for degraded signal transfer between the conventional cable and the PCB. Moreover, data transfer speed is limited by the constraints of the mated plug and the receptacle. A press-fit internal cable enables higher data transfer rates to be achieved when compared to the conventional plug and receptacles. By developing a platform using press-fit internal cables with higher data transfer rates, high-definition and high-quality content can be processed by the platform within specified limits for the content without degraded signals. For example, using a Universal Serial Bus (USB) 3.1 internal cable topology application, a data rate of 10 gigabits per second (Gb/s) is achieved by designing and optimizing the internal cable assembly using press-fit cables. Moreover, the press-fit cable may be a USB 3.1 front panel cable. In some embodiments, the press-fit cable is a cable based on any USB Specification. Further, the press-fit internal cable can also be used with other protocols. For example, in a Serial ATA (SATA) Generation 2 cable topology application, a data rate of 3 Gb/s may apply to the press-fit cable.

Accordingly, embodiments described herein disclose a press-fit input/output (I/O) cable. In embodiments, the press-fit cable includes a plurality of pins coupled to a plurality of wires within the cable, without a plug head. Moreover, the pins are to mate directly with a plurality of vias on a PCB. A receptacle is not present on the PCB circuit board. In this manner, any crosstalk and impedance mismatch as a result of the conventional cable is not present using the press-fit cable. Moreover, the plurality of vias for the press-fit cable on the PCB results in a smaller form factor on the PCB when compared to the receptacle present in a conventional use case.

In the following description, numerous specific details are set forth, such as examples of specific types of processors and system configurations, specific hardware structures, specific architectural and micro architectural details, specific register configurations, specific instruction types, specific system components, specific measurements/heights, specific processor pipeline stages and operation etc. in order to provide a thorough understanding of the present techniques. It will be apparent, however, to one skilled in the art that these specific details need not be employed to practice the present techniques. In other instances, well known components or methods, such as specific and alternative processor architectures, specific logic circuits/code for described algorithms, specific firmware code, specific interconnect operation, specific logic configurations, specific manufacturing techniques and materials, specific compiler implementations, specific expression of algorithms in code, specific power down and gating techniques/logic and other specific operational details of computer system haven't been described in detail in order to avoid unnecessarily obscuring the present techniques.

Although the following embodiments may be described with reference to energy conservation and energy efficiency in specific integrated circuits, such as in computing platforms or microprocessors, other embodiments are applicable to other types of integrated circuits and logic devices. Similar techniques and teachings of embodiments described herein may be applied to other types of circuits or semiconductor devices that may also benefit from better energy efficiency and energy conservation. For example, the disclosed embodiments are not limited to desktop computer systems or Ultrabooks™. And may be also used in other devices, such as handheld devices, tablets, other thin notebooks, systems on a chip (SOC) devices, and embedded applications. Some examples of handheld devices include cellular phones, Internet protocol devices, digital cameras, personal digital assistants (PDAs), and handheld PCs. Embedded applications typically include a microcontroller, a digital signal processor (DSP), a system on a chip, network computers (NetPC), set-top boxes, network hubs, wide area network (WAN) switches, or any other system that can perform the functions and operations taught below. Moreover, the apparatus′, methods, and systems described herein are not limited to physical computing devices, but may also relate to software optimizations for energy conservation and efficiency. As will become readily apparent in the description below, the embodiments of methods, apparatus′, and systems described herein (whether in reference to hardware, firmware, software, or a combination thereof) are vital to a ‘green technology’ future balanced with performance considerations.

As computing systems are advancing, the components therein are becoming more complex. As a result, the interconnect architecture to couple and communicate between the components is also increasing in complexity to ensure bandwidth requirements are met for optimal component operation. Furthermore, different market segments demand different aspects of interconnect architectures to suit the market's needs. For example, servers require higher performance, while the mobile ecosystem is sometimes able to sacrifice overall performance for power savings. Yet, it's a singular purpose of most fabrics to provide highest possible performance with maximum power saving. Below, a number of interconnects are discussed, which would potentially benefit from aspects of the present techniques described herein.

FIG. 1 is a diagram of computing system 100 including a press-fit area 102. The press-fit area 102 is located on a motherboard 104 positioned within the enclosure 106 of the computing system 100. A press-fit cable 108 may include a plurality of pins to enable the cable to be coupled or mated with the press-fit area 102 of the motherboard 104, without using a plug or receptacle. In embodiments, the press-fit cable 108 may be configured to provide data from an electronic device 110 to the motherboard 104. The electronic device 110 may be coupled to a cable 111 is to mate with an interface that is coupled to the press-fit cable 108. Additionally, in embodiments, the press-fit cable 108 may be configured to provide data to the electronic device 110 from the motherboard 104. Further, in embodiments, the press-fit cable includes a compliant pin and a raw cable. The compliant pin is a conducting portion of the cable that mates with the motherboard. For example, the compliant pin may be an eye-of-the-needle pin. The cable is a length of conducting metal surrounded by an insulation material. Examples of a raw cable include, but are not limited to discrete wires, coaxial cables, twin-axial cables, shielded twisted pair (STP), unshielded twisted pair (UTP), and the like.

In some cases, the data transfer between the electronic device 110 and the motherboard 104 occurs at a rate of at least 10 Gb/s. The electronic device 110 may be, for example, a laptop computer, desktop computer, tablet computer, mobile device, server, or cellular phone, among others. Moreover, the electronic device may be television, blue ray player, DVD player, MP3 player, CD player, and the like.

The computing system 100 may include a processor 112 that is adapted to execute stored instructions, as well as a memory device that stores instructions that are executable by the processor 112. The processor 112 can be a single core processor, a multi-core processor, a computing cluster, or any number of other configurations. The processor 112 may be implemented as Complex Instruction Set Computer (CISC) or Reduced Instruction Set Computer (RISC) processors, x86 Instruction set compatible processors, multi-core, or any other microprocessor or central processing unit (CPU). In some embodiments, the processor 112 includes dual-core processor(s), dual-core mobile processor(s), or the like. A memory device may be configured to couple with receptacles 114 on the motherboard 104. The memory device can include random access memory (e.g., SRAM, DRAM, zero capacitor RAM, SONOS, eDRAM, EDO RAM, DDR RAM, RRAM, PRAM, etc.), read only memory (e.g., Mask ROM, PROM, EPROM, EEPROM, etc.), flash memory, or any other suitable memory systems. Accordingly, the receptacles 114 may be designed to receive any such memory device.

In some cases, the processor 112 may be connected through a system bus (e.g., PCI, ISA, PCI-Express, HyperTransport®, NuBus, etc.) to an input/output (I/O) device interface adapted to connect an I/O device via a press-fit cable. In some cases, the I/O device interface is a USB subsystem that connects to the motherboard 104 via a press-fit cable. The computing system 100 may also include, for example, a keyboard and a pointing device, wherein the pointing device may include a touchpad or a touchscreen, a peripheral device such as a camera, a media player, a printer, among others. The computing system 100 could also be a display device or an audio device.

The processor 112 may also be linked through a system bus to a display interface on the motherboard 104 adapted to connect the processor 112 to a display device. The display device may include a display screen that is a built-in component of the computing system 100. The display device may also include a computer monitor, television, or projector, among others, that is externally connected to the computing system 100.

The computing system 100 may also include a storage device 116. The storage device 116 may include a physical memory such as a hard drive, an optical drive, a flash drive, an array of drives, or any combinations thereof. The storage device 116 may also include remote storage drives. The storage device 116 may store instructions thereon to transfer data across a press-fit cable according to a SATA Gen3 protocol at a rate of at least 6 Gb/s. In embodiments, the storage device 116 is coupled to the motherboard 104 via a press-fit cable. The computing system 100 also includes a power supply 120. In some cases, the power supply is a 120 Volt power supply. Further, in embodiments, the power supply includes a fan. The power supply and the fan may be connected to the motherboard 104 via a press-fit cable.

The computing system 100 is described for exemplary purposes only. The computing system 100 may have more or less components, depending on the particular design of the computing system. Further, any system bus can be implemented using a press-fit cable. The press-fit cable can transmit data according to any protocol, including but not limited to PCI, ISA, PCI-Express, SATA, HDMI, DisplayPort, Quick Path Interconnect (QPI), HyperTransport®, NuBus, and USB. Moreover, with the QPI a data rate of 25 Gb/s can be achieved.

FIG. 2 is an illustration of a press-fit cable form factor 200. In some cases, the press-fit cable form factor 200 represents a layout of vias on a motherboard that are to receive the pins of a press-fit cable. For example, the press-fit cable form factor may represent the press-fit area 102 of the motherboard 104 that is to mate with the press-fit cable 108 (FIG. 1).

The press-fit cable form factor 200 has a smaller area when compared to a conventional cable interface. Typically, a conventional cable interface on a motherboard includes a receptacle with a plurality of pins. Using a conventional USB form factor as an example, the area of a internal receptacle typically is over 160 mm² for the conventional form factor. The large area of the conventional form factor can take up a large amount of space on the motherboard.

In the case where the press-fit cable form factor 200 represents a press-fit area on a motherboard, the press-fit cable form factor 200 includes a plurality of vias 202. Using the present techniques, a press-fit form factor 200 can be manufactured with a pitch of 1.5 millimeters (illustrated at reference number 204) or less between each of the vias 202. Accordingly, the press-fit form factor 200 may cover an area of approximately 48 mm² on a motherboard. This results in a smaller form factor when compared to the conventional receptacle and pins used. However, devices that do not include a form factor, the pitch between the pins can be larger than 1.5 mm and still function well at high data rate. For example, other form factors may use pitch of 5.0 mm.

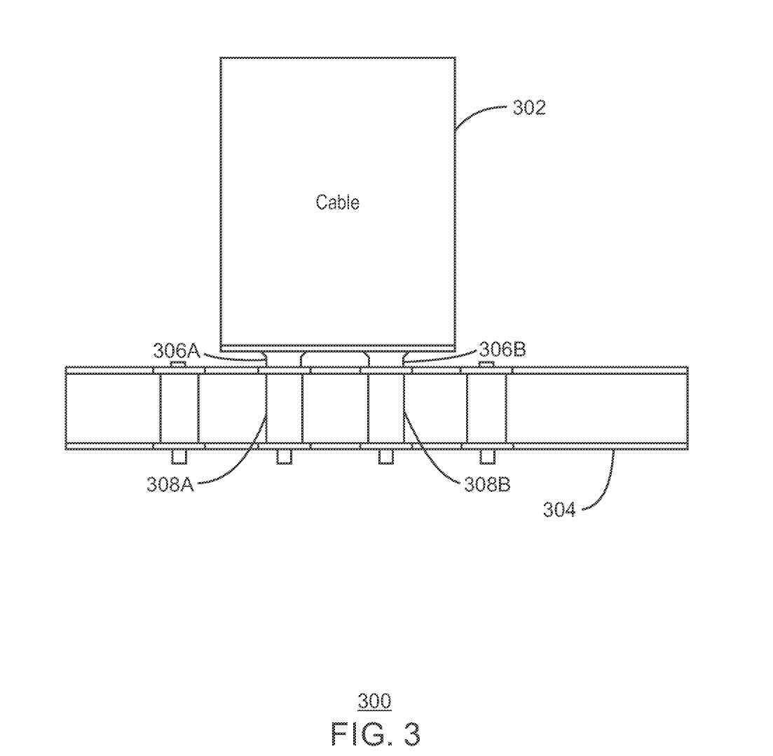

FIG. 3 is an illustration of a press-fit cable 302 connected to a motherboard 304. For ease of illustration, the press-fit cable 302 is illustrated with two press-fit pins 306A and 306B. However, the press-fit cable may use any number of press-fit pins. The press-fit cable enables an internal cable to connect to the motherboard directly, and eliminates the receptacle completely. Eliminating the receptacle saves costs with respect to the bill of materials (BOM) of the platform. Moreover, any electrical parasitic of the receptacle is removed, thereby improving channel performance in terms of less impedance discontinuity and less crosstalk.

The press-fit pin 306A and the press-fit pin 306B each mate with a via 308A and 308B, respectively, on the motherboard 304. In some cases, the via can be a blind via or a plated through hole via. An internal cable of a computing system can be mated or connected to the motherboard using the press-fit cable, without any receptacle present on the motherboard 304. Moreover, the wires of the cable are attached to press-fit pins rather than a traditional plug at the end of the cable.

By removing the receptacle from the motherboard and removing the plug from the cable, high data transfer speeds can be achieved when compared to cables with plugs and receptacles, as the impedance mismatch as well as excessive crosstalk are not present to degrade the data. High, as used herein, refers to a data speed that is greater than the data speed that can be achieved using a conventional plug and receptacle. Additionally, when the press-fit cable is configured for USB3.0, the press-fit cable has smaller form factor than existing USB3.0 internal receptacles. This saves valuable space on the motherboard, and enables smaller devices to be designed, as the motherboard can also be reduced in size.

In some embodiments, the press-fit cable may include a latching mechanism. The latching mechanism can be an alignment notch on each pin of the plurality of pins so that each press-fit cable is seat properly within the vias of the motherboard. Additionally, in embodiments, each pin of the plurality of pins is an eye-of-needle pin.

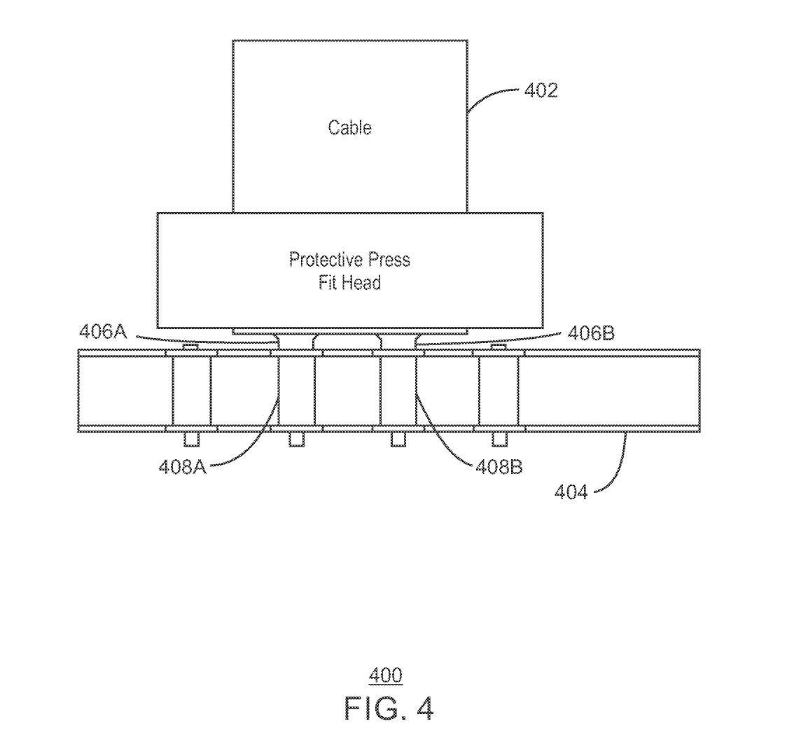

FIG. 4 is an illustration of a press-fit cable 402 connected to a motherboard 404. However, the press-fit cable 402 includes a plurality of pins that are mated to vias on the motherboard 404, similar to FIG. 3. FIG. 4 also includes a protective press-fit head 406. The protective press-fit head can be used to protect the plurality of pins that are directly connected to wires within the cable 402.

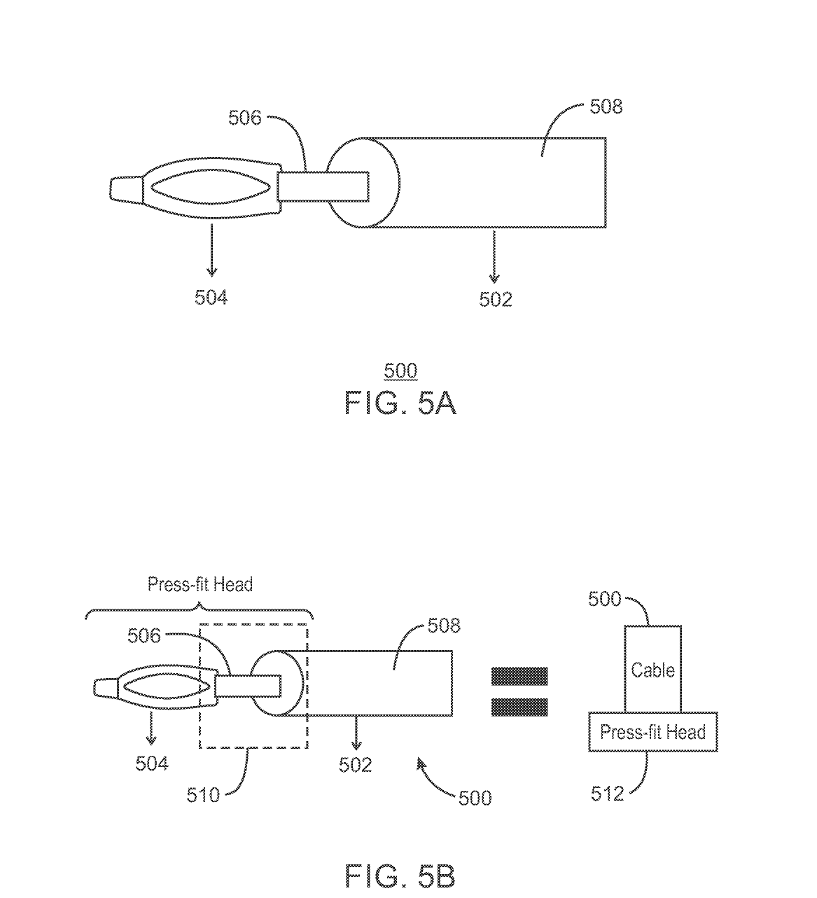

FIG. 5A is an illustration of a press-fit internal cable 500. As used herein, an internal cable is a cable that is within the housing of an electronic device. The press-fit internal cable 500 includes a raw cable 502 and a plurality of compliant pins 504. The raw cable 502 includes conducting metal 506 surrounded by an insulation material 508. The plurality of compliant pins 504 may be any pin type that can be mated with a motherboard. In some cases, the plurality of compliant pins 504 are eye-of-needle pins.

FIG. 5B is an illustration of a press-fit internal cable 500 with an overmold 510. Similar to FIG. 5A, the press-fit internal cable 500 includes a raw cable 502 and a plurality of compliant pins 504. The raw cable 502 includes conducting metal 506 surrounded by an insulation material 508. The conducting metal 506 is surrounded by an overmold 510. In embodiments, the overmold is a layer of material or protective header surrounding the conducting metal 506. The overmold can be formed around the insulation material 508 and provide a protective cover for the conducting metal 506 as it transitions to the plurality of compliant pins 504. Additionally, in some embodiments the overmold 510 and the plurality of compliant pins 504 may be included within a press-fit head 512.

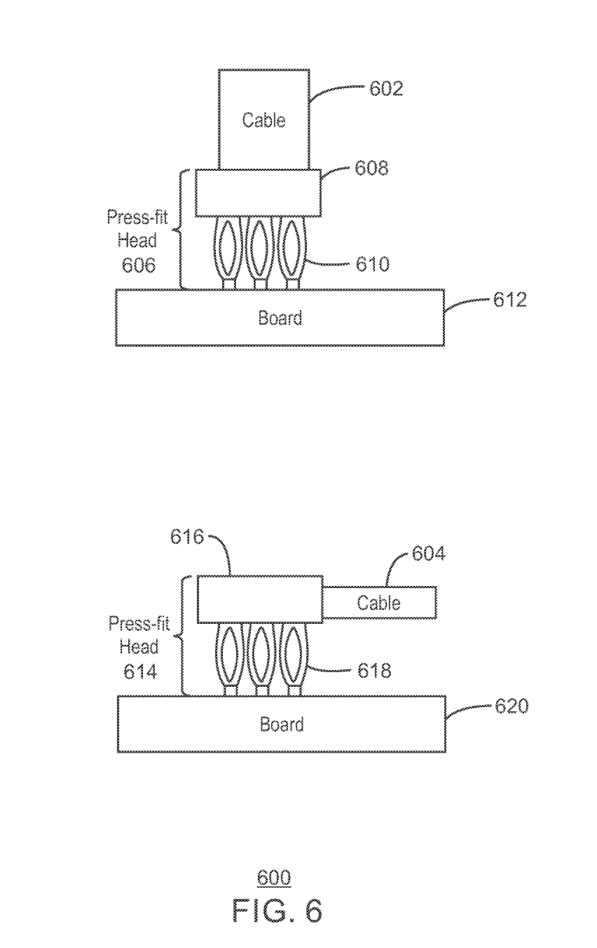

FIG. 6 is an illustration of a vertical press-fit internal cable 602 and a horizontal press-fit internal cable 604. The vertical press-fit internal cable 602 may be coupled with a press-fit head 606 that includes an overmold 608 and a plurality of compliant pins 610. The plurality of complaint pins 610 may be coupled with a motherboard 612. Similarly, the horizontal press-fit internal cable 604 may be coupled with a press-fit head 614 that includes an overmold 616 and a plurality of compliant pins 618. The plurality of complaint pins 618 may be coupled with a motherboard 620. As illustrated, the press-fit cable can be implemented in a horizontal or vertical fashion.

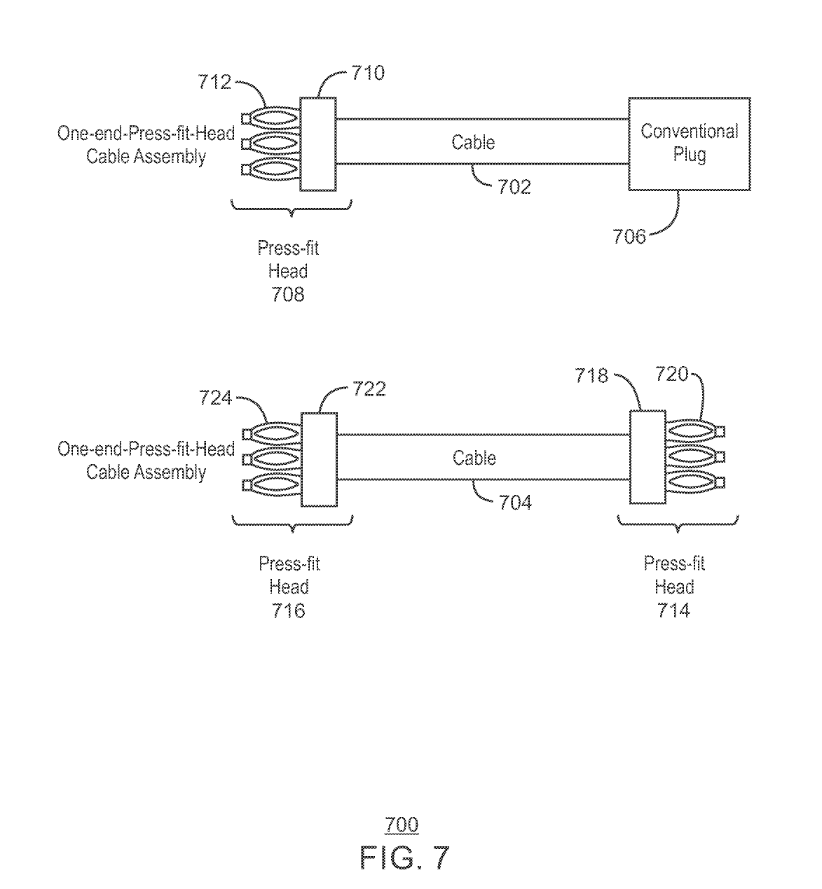

FIG. 7 is an illustration of a one end press-fit cable 702 and a two end press-fit cable 704. The one end press-fit cable 702 may be coupled with a conventional plug 706 and a press-fit head 708. In embodiments, the press-fit head may include an overmold 710 and a plurality of compliant pins 712. The two end press-fit cable 704 may be coupled with a press-fit head 714 and a press-fit head 716. In embodiments, the press-fit head 714 may include an overmold 718 and a plurality of compliant pins 720. Further, in embodiments, the press-fit head 716 may include an overmold 722 and a plurality of compliant pins 724. The press-fit cable 702 or the press-fit cable 704 can be implemented in an electronic device according to a particular design of the electronic device.

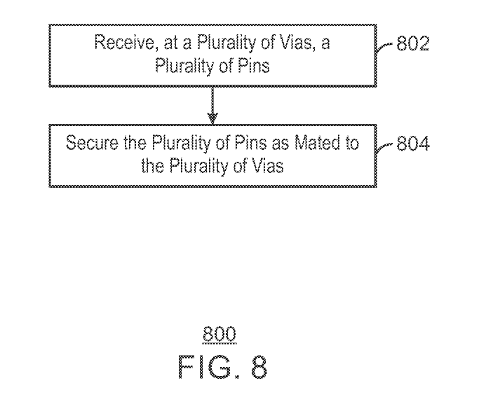

FIG. 8 is a process flow diagram of a method 800 for receiving a press-fit cable at a circuit board. The method 800 may include locating a plurality of vias on a circuit board. The circuit board may be a motherboard of a computing system as described above. Additionally, the vias may be plate through hole (PTH) vias, or the vias may be blind vias. At block 802, a plurality of pins is received by the plurality of vias, where each pin of the plurality of pins is configured to be press-fit to the circuit board. In this manner, the footprint of vias on the circuit board can be as small as permitted by manufacturing processes. In some cases, the footprint of vias on the circuit board includes a pitch of approximately 1.5 millimeters or less. At block 804, the plurality of pins may be secured as mated to the plurality of vias. In examples, the plurality of pins are press-fit pins that automatically secure when inserted in the plurality of vias. In other embodiments, the plurality of pins are eye-of-needle pins that are automatically secured when mated to the plurality of vias. Further, in embodiments, each pin of the plurality of pins is notched to enable the pins to lock in place when inserted into the plurality of vias.

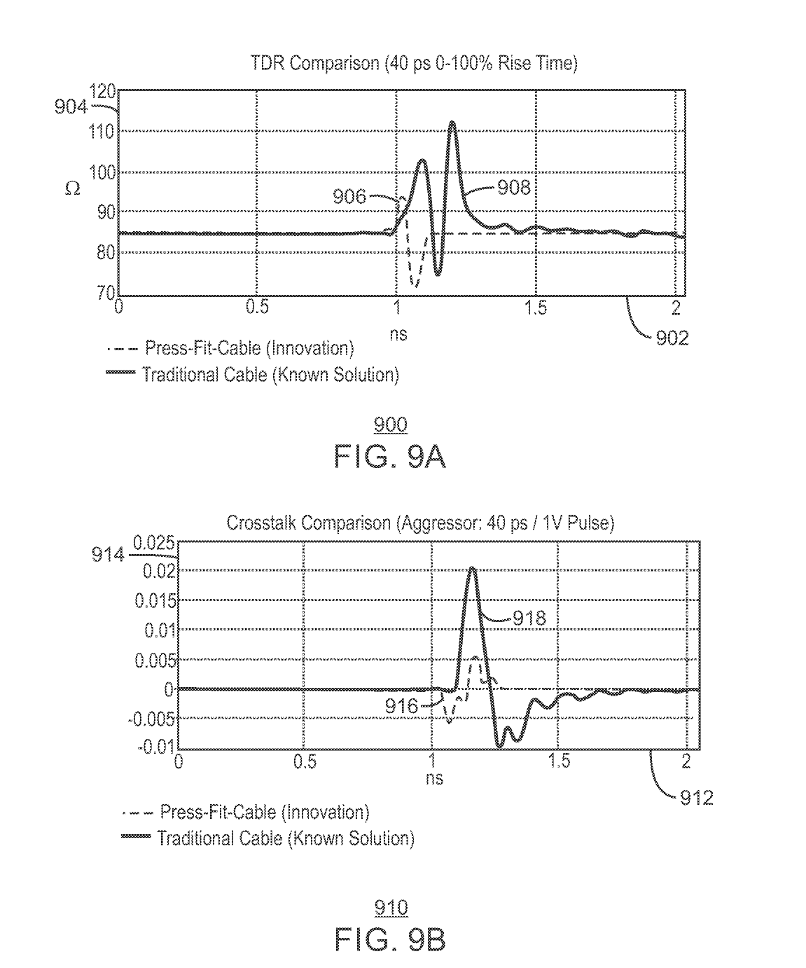

FIG. 9A is a time domain reflectometer plot 900 comparing impedance discontinuities. In particular, the time domain reflectometer (TDR) plot 900 compares the impedance discontinuity of a conventional cable and the impedance discontinuity of the press-fit cable according to the present techniques. A TDR is used to plot an impedance discontinuity by observing an elapsed time while applying a stimulus to each cable. In examples, the stimulus to each cable is a step function. Accordingly, an axis at reference number 902 measures the elapsed time, while an axis at reference number 904 measures the impedance observed at each cable. A dashed line 906 represents the press-fit cable according to the present techniques. A solid line 908 represents a conventional cable.

As illustrated, the impedance is nominal for both cables at approximately 85 Ohms (Ω) until 1 nanosecond (ns) of elapsed time. An impedance discontinuity occurs after 1 ns for the press-fit cable represented by the dashed line 906, and the discontinuity lasts approximately 0.2 ns, until an elapsed time of 1.2 ns. An impedance discontinuity also occurs after 1 ns for the conventional cable represented by the solid line 908, and the discontinuity lasts approximately 0.6 ns, until an elapsed time of 1.6 ns. The TDR plot 900 illustrates a smaller impedance discontinuity for the press-fit cable represented by the dashed line 906 when compared to the conventional cable represented by the solid line 908.

FIG. 9B is a time domain transmission plot 910 comparing a crosstalk response. In particular, the time domain transmission (TDT) plot 910 compares the crosstalk, in voltage, of a conventional cable and the crosstalk, in voltage, of the press-fit cable according to the present techniques. A TDT is used to plot the crosstalk by observing the noise coupled from a transmitted pulse (the aggressor) through an elapsed time. In examples, the pulse is a 1 Volt (V) and 40 picosecond rise time stimulus applied to each cable. Accordingly, an axis at reference number 912 measures the elapsed time, while an axis at reference number 914 measures the voltage observed at each cable. A dashed line 916 represents the press-fit cable according to the present techniques. A solid line 918 represents a conventional cable.

As illustrated, the crosstalk voltage is nominal at 0 V for both cables until 1 nanosecond (ns) of elapsed time. Crosstalk occurs after 1 ns for the press-fit cable represented by the dashed line 916, and the crosstalk lasts approximately 0.3 ns, until an elapsed time of 1.3 ns. Crosstalk also occurs after 1 ns for the conventional cable represented by the solid line 918, and the crosstalk lasts approximately 1.0 ns, until an elapsed time of 2.0 ns. The TDT plot 910 illustrates a smaller amount of crosstalk for the press-fit cable represented by the dashed line 916 when compared to the crosstalk on conventional cable represented by the solid line 918.

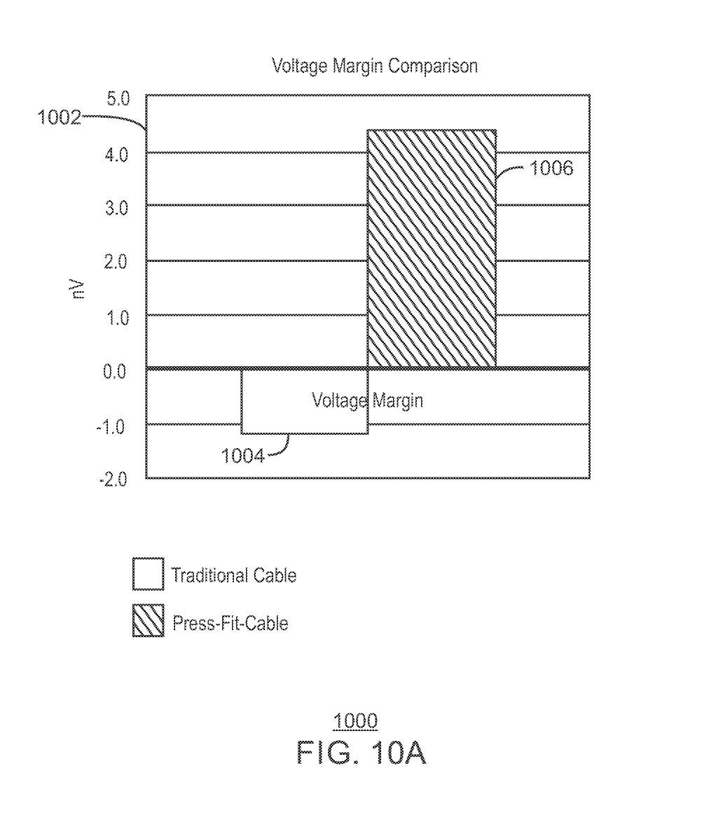

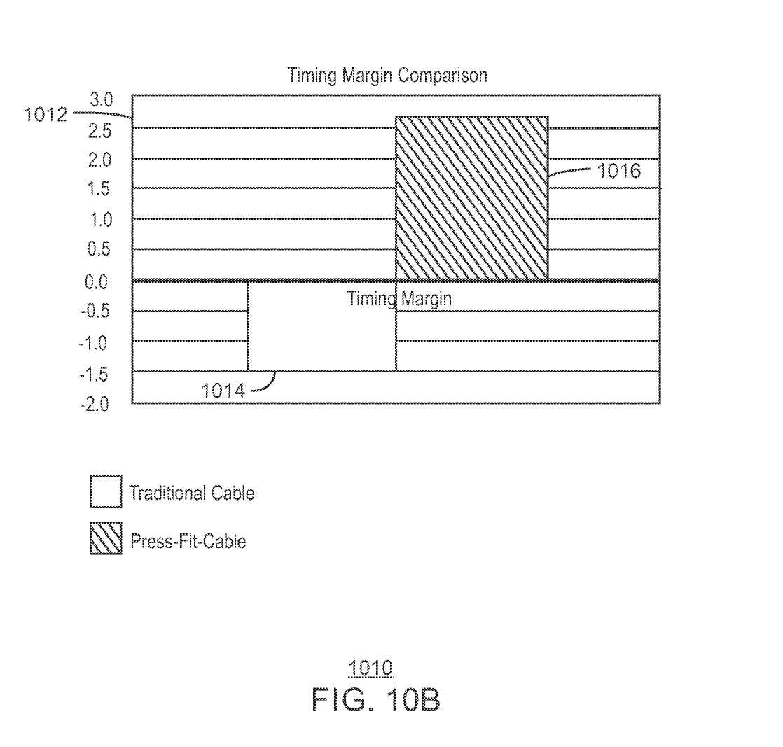

FIG. 10A is a voltage margin comparison 1000 for a traditional cable and a press-fit cable according to the present techniques. The voltage margin comparison 1000 measures a voltage margin 1002 for each cable for the same channel simulation. The traditional cable is represented by a bar at reference number 1004. A press-fit cable is represented by a bar at reference number 1006. The traditional cable that mates with a receptacle has excessive crosstalk and impedance discontinuity resulting in a negative voltage margin at reference number 1004. The press-fit cable has a positive voltage margin at reference number 1006. The positive voltage margin for the press-fit cable indicates that the data transmitted through press-fit cable can be correctly recovered at receiver without an error. As a result, the press-fit cable can transmit data at a rate of at least 10 Gb/s.

FIG. 10B is a timing margin comparison 1010 for a traditional cable and a press-fit cable according to the present techniques. Similarly to the voltage margin comparison 1000, the timing margin comparison 1010 measures a timing margin 1012 for each cable for the same channel simulation. The traditional cable is represented by a bar at reference number 1014. A press-fit cable is represented by a bar at reference number 1016. The traditional cable that mates with a receptacle has a negative timing margin at reference number 1014. The press-fit cable has a positive timing margin at reference number 1016. The positive timing margin for the press-fit indicates that the data transmitted through press-fit cable can be correctly recovered at receiver without an error. As a result, the press-fit cable can transmit data at a rate of at least 10 Gb/s.

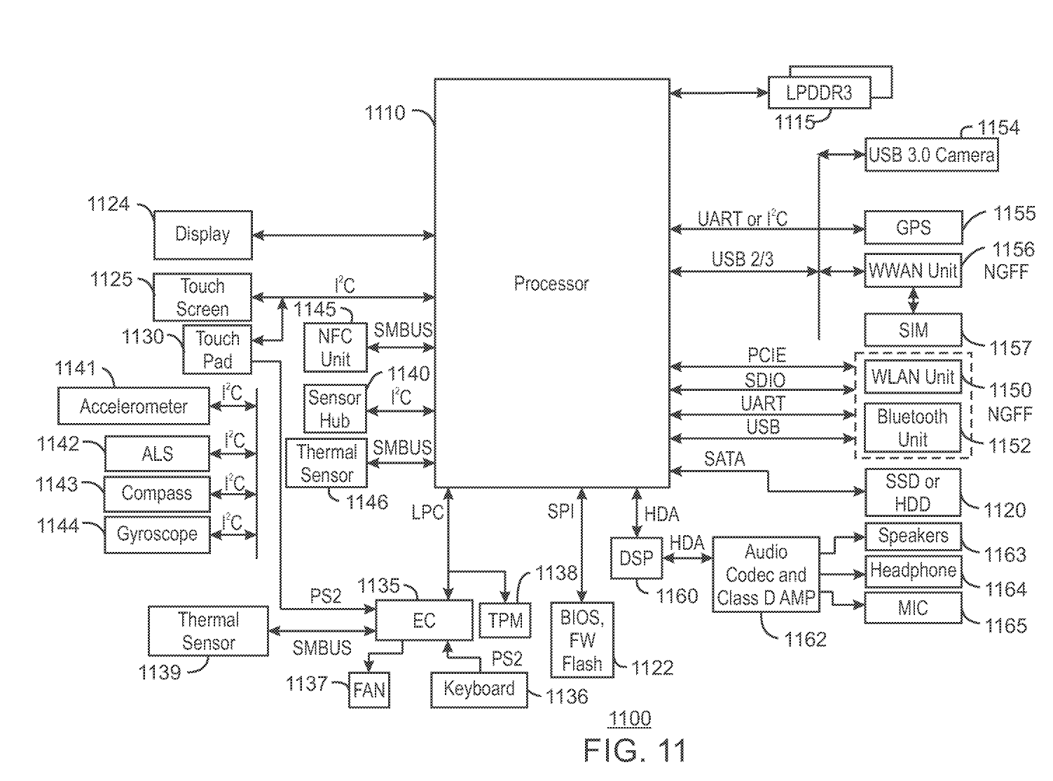

Referring now to FIG. 11, a block diagram of components present in a computer system in accordance with an embodiment of the present techniques is illustrated. As shown in FIG. 11, system 1100 includes any combination of components. These components may be implemented as ICs, portions thereof, discrete electronic devices, or other modules, logic, hardware, software, firmware, or a combination thereof adapted in a computer system, or as components otherwise incorporated within a chassis of the computer system. Each of these components may be interconnected using press-fit cables. Note also that the block diagram of FIG. 11 is intended to show a high level view of many components of the computer system. However, it is to be understood that some of the components shown may be omitted, additional components may be present, and different arrangement of the components shown may occur in other implementations. As a result, the present techniques described above may be implemented in any portion of one or more of the interconnects illustrated or described below.

As seen in FIG. 11, a processor 1110, in one embodiment, includes a microprocessor, multi-core processor, multithreaded processor, an ultra low voltage processor, an embedded processor, or other known processing element. In the illustrated implementation, processor 1110 acts as a main processing unit and central hub for communication with many of the various components of the system 1100. As one example, processor 1100 is implemented as a system on a chip (SoC). As a specific illustrative example, processor 1110 includes an Intel® Architecture Core™-based processor such as an i3, i5, i7 or another such processor available from Intel Corporation, Santa Clara, Calif. However, understand that other low power processors such as available from Advanced Micro Devices, Inc. (AMD) of Sunnyvale, Calif., a MIPS-based design from MIPS Technologies, Inc. of Sunnyvale, Calif., an ARM-based design licensed from ARM Holdings, Ltd. or customer thereof, or their licensees or adopters may instead be present in other embodiments such as an Apple A5/A6 processor, a Qualcomm Snapdragon processor, or TI OMAP processor. Note that many of the customer versions of such processors are modified and varied; however, they may support or recognize a specific instructions set that performs defined algorithms as set forth by the processor licensor. Here, the microarchitectural implementation may vary, but the architectural function of the processor is usually consistent. Certain details regarding the architecture and operation of processor 1110 in one implementation will be discussed further below to provide an illustrative example.

Processor 1110, in one embodiment, communicates with a system memory 1115. As an illustrative example, an embodiment can be implemented via multiple memory devices to provide for a given amount of system memory. As examples, the memory can be in accordance with a Joint Electron Devices Engineering Council (JEDEC) low power double data rate (LPDDR)-based design such as the current LPDDR2 standard according to JEDEC JESD 209-2E (published April 2009), or a next generation LPDDR standard to be referred to as LPDDR3 or LPDDR4 that will offer extensions to LPDDR2 to increase bandwidth. In various implementations the individual memory devices may be of different package types such as single die package (SDP), dual die package (DDP) or quad die package (Q17P). These devices, in some embodiments, are directly soldered onto a motherboard to provide a lower profile solution, while in other embodiments the devices are configured as one or more memory modules that in turn couple to the motherboard by a given connector. And of course, other memory implementations are possible such as other types of memory modules, e.g., dual inline memory modules (DIMMs) of different varieties including but not limited to microDIMMs, MiniDIMMs. In a particular illustrative embodiment, memory is sized between 2 GB and 16 GB, and may be configured as a DDR3LM package or an LPDDR2 or LPDDR3 memory that is soldered onto a motherboard via a ball grid array (BGA).

To provide for persistent storage of information such as data, applications, one or more operating systems and so forth, a mass storage 1120 may also couple to processor 1110. In various embodiments, to enable a thinner and lighter system design as well as to improve system responsiveness, this mass storage may be implemented via a SSD. However in other embodiments, the mass storage may primarily be implemented using a hard disk drive (HDD) with a smaller amount of SSD storage to act as a SSD cache to enable non-volatile storage of context state and other such information during power down events so that a fast power up can occur on re-initiation of system activities. Also shown in FIG. 11, a flash device 1122 may be coupled to processor 1110, e.g., via a serial peripheral interface (SPI). This flash device may provide for non-volatile storage of system software, including a basic input/output software (BIOS) as well as other firmware of the system.

In various embodiments, mass storage of the system is implemented by a SSD alone or as a disk, optical or other drive with an SSD cache. In some embodiments, the mass storage is implemented as a SSD or as a HDD along with a restore (RST) cache module. In various implementations, the HDD provides for storage of between 320 GB-4 terabytes (TB) and upward while the RST cache is implemented with a SSD having a capacity of 24 GB-256 GB. Note that such SSD cache may be configured as a single level cache (SLC) or multi-level cache (MLC) option to provide an appropriate level of responsiveness. In an SSD-only option, the module may be accommodated in various locations such as in a mSATA or NGFF slot. As an example, an SSD has a capacity ranging from 120 GB-1 TB.

Various input/output (IO) devices may be present within system 1100. Specifically shown in the embodiment of FIG. 11 is a display 1124 which may be a high definition LCD or LED panel configured within a lid portion of the chassis. This display panel may also provide for a touch screen 1125, e.g., adapted externally over the display panel such that via a user's interaction with this touch screen, user inputs can be provided to the system to enable desired operations, e.g., with regard to the display of information, accessing of information and so forth. In one embodiment, display 1124 may be coupled to processor 1110 via a display interconnect that can be implemented as a high performance graphics interconnect. Touch screen 1125 may be coupled to processor 1110 via another interconnect, which in an embodiment can be an I²C interconnect. As further shown in FIG. 11, in addition to touch screen 1125, user input by way of touch can also occur via a touch pad 1130 which may be configured within the chassis and may also be coupled to the same I²C interconnect as touch screen 1125.

The display panel may operate in multiple modes. In a first mode, the display panel can be arranged in a transparent state in which the display panel is transparent to visible light. In various embodiments, the majority of the display panel may be a display except for a bezel around the periphery. When the system is operated in a notebook mode and the display panel is operated in a transparent state, a user may view information that is presented on the display panel while also being able to view objects behind the display. In addition, information displayed on the display panel may be viewed by a user positioned behind the display. Or the operating state of the display panel can be an opaque state in which visible light does not transmit through the display panel.

In a tablet mode the system is folded shut such that the back display surface of the display panel comes to rest in a position such that it faces outwardly towards a user, when the bottom surface of the base panel is rested on a surface or held by the user. In the tablet mode of operation, the back display surface performs the role of a display and user interface, as this surface may have touch screen functionality and may perform other known functions of a conventional touch screen device, such as a tablet device. To this end, the display panel may include a transparency-adjusting layer that is disposed between a touch screen layer and a front display surface. In some embodiments the transparency-adjusting layer may be an electrochromic layer (EC), a LCD layer, or a combination of EC and LCD layers.

In various embodiments, the display can be of different sizes, e.g., an 11.6″ or a 13.3″ screen, and may have a 16:9 aspect ratio, and at least 300 nits brightness. Also the display may be of full high definition (HD) resolution (at least 1920×1080p), be compatible with an embedded display port (eDP), and be a low power panel with panel self refresh.

As to touch screen capabilities, the system may provide for a display multi-touch panel that is multi-touch capacitive and being at least 5 finger capable. And in some embodiments, the display may be 10 finger capable. In one embodiment, the touch screen is accommodated within a damage and scratch-resistant glass and coating (e.g., Gorilla Glass™ or Gorilla Glass 2™) for low friction to reduce “finger burn” and avoid “finger skipping”. To provide for an enhanced touch experience and responsiveness, the touch panel, in some implementations, has multi-touch functionality, such as less than 2 frames (30 Hz) per static view during pinch zoom, and single-touch functionality of less than 1 cm per frame (30 Hz) with 200 ms (lag on finger to pointer). The display, in some implementations, supports edge-to-edge glass with a minimal screen bezel that is also flush with the panel surface, and limited IO interference when using multi-touch.

For perceptual computing and other purposes, various sensors may be present within the system and may be coupled to processor 1110 in different manners. Certain inertial and environmental sensors may couple to processor 1110 through a sensor hub 1140, e.g., via an I²C interconnect. In the embodiment shown in FIG. 11, these sensors may include an accelerometer 1141, an ambient light sensor (ALS) 1142, a compass 1143 and a gyroscope 1144. Other environmental sensors may include one or more thermal sensors 1146 which in some embodiments couple to processor 1110 via a system management bus (SMBus) bus.

Using the various inertial and environmental sensors present in a platform, many different use cases may be realized. These use cases enable advanced computing operations including perceptual computing and also allow for enhancements with regard to power management/battery life, security, and system responsiveness.

For example with regard to power management/battery life issues, based at least on part on information from an ambient light sensor, the ambient light conditions in a location of the platform are determined and intensity of the display controlled accordingly. Thus, power consumed in operating the display is reduced in certain light conditions.

As to security operations, based on context information obtained from the sensors such as location information, it may be determined whether a user is allowed to access certain secure documents. For example, a user may be permitted to access such documents at a work place or a home location. However, the user is prevented from accessing such documents when the platform is present at a public location. This determination, in one embodiment, is based on location information, e.g., determined via a GPS sensor or camera recognition of landmarks. Other security operations may include providing for pairing of devices within a close range of each other, e.g., a portable platform as described herein and a user's desktop computer, mobile telephone or so forth. Certain sharing, in some implementations, is realized via near field communication when these devices are so paired. However, when the devices exceed a certain range, such sharing may be disabled. Furthermore, when pairing a platform as described herein and a smartphone, an alarm may be configured to be triggered when the devices move more than a predetermined distance from each other, when in a public location. In contrast, when these paired devices are in a safe location, e.g., a work place or home location, the devices may exceed this predetermined limit without triggering such alarm.

Responsiveness may also be enhanced using the sensor information. For example, even when a platform is in a low power state, the sensors may still be enabled to run at a relatively low frequency. Accordingly, any changes in a location of the platform, e.g., as determined by inertial sensors, GPS sensor, or so forth is determined. If no such changes have been registered, a faster connection to a previous wireless hub such as a Wi-Fi™ access point or similar wireless enabler occurs, as there is no need to scan for available wireless network resources in this case. Thus, a greater level of responsiveness when waking from a low power state is achieved.

It is to be understood that many other use cases may be enabled using sensor information obtained via the integrated sensors within a platform as described herein, and the above examples are only for purposes of illustration. Using a system as described herein, a perceptual computing system may allow for the addition of alternative input modalities, including gesture recognition, and enable the system to sense user operations and intent.

In some embodiments one or more infrared or other heat sensing elements, or any other element for sensing the presence or movement of a user may be present. Such sensing elements may include multiple different elements working together, working in sequence, or both. For example, sensing elements include elements that provide initial sensing, such as light or sound projection, followed by sensing for gesture detection by, for example, an ultrasonic time of flight camera or a patterned light camera.

Also in some embodiments, the system includes a light generator to produce an illuminated line. In some embodiments, this line provides a visual cue regarding a virtual boundary, namely an imaginary or virtual location in space, where action of the user to pass or break through the virtual boundary or plane is interpreted as an intent to engage with the computing system. In some embodiments, the illuminated line may change colors as the computing system transitions into different states with regard to the user. The illuminated line may be used to provide a visual cue for the user of a virtual boundary in space, and may be used by the system to determine transitions in state of the computer with regard to the user, including determining when the user wishes to engage with the computer.

In some embodiments, the computer senses user position and operates to interpret the movement of a hand of the user through the virtual boundary as a gesture indicating an intention of the user to engage with the computer. In some embodiments, upon the user passing through the virtual line or plane the light generated by the light generator may change, thereby providing visual feedback to the user that the user has entered an area for providing gestures to provide input to the computer.

Display screens may provide visual indications of transitions of state of the computing system with regard to a user. In some embodiments, a first screen is provided in a first state in which the presence of a user is sensed by the system, such as through use of one or more of the sensing elements.

In some implementations, the system acts to sense user identity, such as by facial recognition. Here, transition to a second screen may be provided in a second state, in which the computing system has recognized the user identity, where this second the screen provides visual feedback to the user that the user has transitioned into a new state. Transition to a third screen may occur in a third state in which the user has confirmed recognition of the user.

In some embodiments, the computing system may use a transition mechanism to determine a location of a virtual boundary for a user, where the location of the virtual boundary may vary with user and context. The computing system may generate a light, such as an illuminated line, to indicate the virtual boundary for engaging with the system. In some embodiments, the computing system may be in a waiting state, and the light may be produced in a first color. The computing system may detect whether the user has reached past the virtual boundary, such as by sensing the presence and movement of the user using sensing elements.

In some embodiments, if the user has been detected as having crossed the virtual boundary (such as the hands of the user being closer to the computing system than the virtual boundary line), the computing system may transition to a state for receiving gesture inputs from the user, where a mechanism to indicate the transition may include the light indicating the virtual boundary changing to a second color.

In some embodiments, the computing system may then determine whether gesture movement is detected. If gesture movement is detected, the computing system may proceed with a gesture recognition process, which may include the use of data from a gesture data library, which may reside in memory in the computing device or may be otherwise accessed by the computing device.

If a gesture of the user is recognized, the computing system may perform a function in response to the input, and return to receive additional gestures if the user is within the virtual boundary. In some embodiments, if the gesture is not recognized, the computing system may transition into an error state, where a mechanism to indicate the error state may include the light indicating the virtual boundary changing to a third color, with the system returning to receive additional gestures if the user is within the virtual boundary for engaging with the computing system.

As mentioned above, in other embodiments the system can be configured as a convertible tablet system that can be used in at least two different modes, a tablet mode and a notebook mode. The convertible system may have two panels, namely a display panel and a base panel such that in the tablet mode the two panels are disposed in a stack on top of one another. In the tablet mode, the display panel faces outwardly and may provide touch screen functionality as found in conventional tablets. In the notebook mode, the two panels may be arranged in an open clamshell configuration.

In various embodiments, the accelerometer may be a 3-axis accelerometer having data rates of at least 50 Hz. A gyroscope may also be included, which can be a 3-axis gyroscope. In addition, an e-compass/magnetometer may be present. Also, one or more proximity sensors may be provided (e.g., for lid open to sense when a person is in proximity (or not) to the system and adjust power/performance to extend battery life). For some OS's Sensor Fusion capability including the accelerometer, gyroscope, and compass may provide enhanced features. In addition, via a sensor hub having a real-time clock (RTC), a wake from sensors mechanism may be realized to receive sensor input when a remainder of the system is in a low power state.

In some embodiments, an internal lid/display open switch or sensor to indicate when the lid is closed/open, and can be used to place the system into Connected Standby or automatically wake from Connected Standby state. Other system sensors can include ACPI sensors for internal processor, memory, and skin temperature monitoring to enable changes to processor and system operating states based on sensed parameters.

In an embodiment, the OS may be a Microsoft® Windows® 8 OS that implements Connected Standby (also referred to herein as Win8 CS). Windows 8 Connected Standby or another OS having a similar state can provide, via a platform as described herein, very low ultra idle power to enable applications to remain connected, e.g., to a cloud-based location, at very low power consumption. The platform can supports 3 power states, namely screen on (normal); Connected Standby (as a default “off” state); and shutdown (zero watts of power consumption). Thus in the Connected Standby state, the platform is logically on (at minimal power levels) even though the screen is off. In such a platform, power management can be made to be transparent to applications and maintain constant connectivity, in part due to offload technology to enable the lowest powered component to perform an operation. In embodiments, a power delivery controller operating under a Microsoft® Windows® OS may be shared such that power is provided to peripheral devices according to the present techniques.

Also seen in FIG. 11, various peripheral devices may couple to processor 1110 via a low pin count (LPC) interconnect. In the embodiment shown, various components can be coupled through an embedded controller 1135. Such components can include a keyboard 1136 (e.g., coupled via a PS2 interface), a fan 1137, and a thermal sensor 1139. In some embodiments, touch pad 1130 may also couple to EC 1135 via a PS2 interface. In addition, a security processor such as a trusted platform module (TPM) 1138 in accordance with the Trusted Computing Group (TCG) TPM Specification Version 1.2, dated Oct. 2, 2003, may also couple to processor 1110 via this LPC interconnect. However, understand the scope of the present techniques is not limited in this regard and secure processing and storage of secure information may be in another protected location such as a static random access memory (SRAM) in a security coprocessor, or as encrypted data blobs that are only decrypted when protected by a secure enclave (SE) processor mode. In some cases, the devices connected via the LPC interconnect can share a power delivery controller as described herein.

In a particular implementation, peripheral ports may include a high definition media interface (HDMI) connector (which can be of different form factors such as full size, mini or micro); one or more USB ports, such as full-size external ports in accordance with the Universal Serial Bus Revision 3.0 Specification (November 2008), with each port able to be powered for charging of USB devices (such as smartphones) when the system is in Connected Standby state and is plugged into AC wall power. Each port may share a power delivery controller as described herein. In addition, one or more Thunderbolt™ ports can be provided. Other ports may include an externally accessible card reader such as a full size SD-XC card reader and/or a SIM card reader for WWAN (e.g., an 8 pin card reader). For audio, a 3.5 mm jack with stereo sound and microphone capability (e.g., combination functionality) can be present, with support for jack detection (e.g., headphone only support using microphone in the lid or headphone with microphone in cable). In some embodiments, this jack can be re-taskable between stereo headphone and stereo microphone input. Also, a power jack can be provided for coupling to an AC brick.

System 1100 can communicate with external devices in a variety of manners, including wirelessly. In the embodiment shown in FIG. 11, various wireless modules, each of which can correspond to a radio configured for a particular wireless communication protocol, are present. One manner for wireless communication in a short range such as a near field may be via a near field communication (NFC) unit 1145 which may communicate, in one embodiment with processor 1110 via an SMBus. Note that via this NFC unit 1145, devices in close proximity to each other can communicate. For example, a user can enable system 1100 to communicate with another (e.g.,) portable device such as a smartphone of the user via adapting the two devices together in close relation and enabling transfer of information such as identification information payment information, data such as image data or so forth. Wireless power transfer may also be performed using a NFC system.

Using the NFC unit described herein, users can bump devices side-to-side and place devices side-by-side for near field coupling functions (such as near field communication and wireless power transfer (WPT)) by leveraging the coupling between coils of one or more of such devices. More specifically, embodiments provide devices with strategically shaped, and placed, ferrite materials, to provide for better coupling of the coils. Each coil has an inductance associated with it, which can be chosen in conjunction with the resistive, capacitive, and other features of the system to enable a common resonant frequency for the system.

As further seen in FIG. 11, additional wireless units can include other short range wireless engines including a WLAN unit 1150 and a Bluetooth unit 1152. Using WLAN unit 1150, Wi-Fi™ communications in accordance with a given Institute of Electrical and Electronics Engineers (IEEE) 802.11 standard can be realized, while via Bluetooth unit 1152, short range communications via a Bluetooth protocol can occur. These units may communicate with processor 1110 via, e.g., a USB link or a universal asynchronous receiver transmitter (UART) link. Or these units may couple to processor 1110 via an interconnect according to a Peripheral Component Interconnect Express™ (PCIe™) protocol, e.g., in accordance with the PCI Express™ Specification Base Specification version 3.0 (published Jan. 17, 2007), or another such protocol such as a serial data input/output (SDIO) standard. Of course, the actual physical connection between these peripheral devices, which may be configured on one or more add-in cards, can be by way of the NGFF connectors adapted to a motherboard.

In addition, wireless wide area communications, e.g., according to a cellular or other wireless wide area protocol, can occur via a WWAN unit 1156 which in turn may couple to a subscriber identity module (SIM) 1157. In addition, to enable receipt and use of location information, a GPS module 1155 may also be present. Note that in the embodiment shown in FIG. 11, WWAN unit 1156 and an integrated capture device such as a camera module 1154 may communicate via a given USB protocol such as a USB 2.0 or 3.0 link, or a UART or I²C protocol. Again the actual physical connection of these units can be via adaptation of a NGFF add-in card to an NGFF connector configured on the motherboard.

In a particular embodiment, wireless functionality can be provided modularly, e.g., with a WiFi™ 802.11 ac solution (e.g., add-in card that is backward compatible with IEEE 802.11 abgn) with support for Windows 8 CS. This card can be configured in an internal slot (e.g., via an NGFF adapter). An additional module may provide for Bluetooth capability (e.g., Bluetooth 4.0 with backwards compatibility) as well as Intel® Wireless Display functionality. In addition NFC support may be provided via a separate device or multi-function device, and can be positioned as an example, in a front right portion of the chassis for easy access. A still additional module may be a WWAN device that can provide support for 3G/4G/LTE and GPS. This module can be implemented in an internal (e.g., NGFF) slot. Integrated antenna support can be provided for WiFi™, Bluetooth, WWAN, NFC and GPS, enabling seamless transition from WiFi™ to WWAN radios, wireless gigabit (WiGig) in accordance with the Wireless Gigabit Specification (July 2010), and vice versa.

As described above, an integrated camera can be incorporated in the lid. As one example, this camera can be a high resolution camera, e.g., having a resolution of at least 2.0 megapixels (MP) and extending to 8.0 MP and beyond.

To provide for audio inputs and outputs, an audio processor can be implemented via a digital signal processor (DSP) 1160, which may couple to processor 1110 via a high definition audio (HDA) link. Similarly, DSP 1160 may communicate with an integrated coder/decoder (CODEC) and amplifier 1162 that in turn may couple to output speakers 1163 which may be implemented within the chassis. Similarly, amplifier and CODEC 1162 can be coupled to receive audio inputs from a microphone 1165 which in an embodiment can be implemented via dual array microphones (such as a digital microphone array) to provide for high quality audio inputs to enable voice-activated control of various operations within the system. Note also that audio outputs can be provided from amplifier/CODEC 1162 to a headphone jack 1164. Although shown with these particular components in the embodiment of FIG. 11, understand the scope of the present techniques is not limited in this regard.

In a particular embodiment, the digital audio codec and amplifier are capable of driving the stereo headphone jack, stereo microphone jack, an internal microphone array and stereo speakers. In different implementations, the codec can be integrated into an audio DSP or coupled via an HD audio path to a peripheral controller hub (PCH). In some implementations, in addition to integrated stereo speakers, one or more bass speakers can be provided, and the speaker solution can support DTS audio.

In some embodiments, processor 1110 may be powered by an external voltage regulator (VR) and multiple internal voltage regulators that are integrated inside the processor die, referred to as fully integrated voltage regulators (FIVRs). The use of multiple FIVRs in the processor enables the grouping of components into separate power planes, such that power is regulated and supplied by the FIVR to only those components in the group. During power management, a given power plane of one FIVR may be powered down or off when the processor is placed into a certain low power state, while another power plane of another FIVR remains active, or fully powered.

In one embodiment, a sustain power plane can be used during some deep sleep states to power on the I/O pins for several I/O signals, such as the interface between the processor and a PCH, the interface with the external VR and the interface with EC 1135. This sustain power plane also powers an on-die voltage regulator that supports the on-board SRAM or other cache memory in which the processor context is stored during the sleep state. The sustain power plane is also used to power on the processor's wakeup logic that monitors and processes the various wakeup source signals.

During power management, while other power planes are powered down or off when the processor enters certain deep sleep states, the sustain power plane remains powered on to support the above-referenced components. However, this can lead to unnecessary power consumption or dissipation when those components are not needed. To this end, embodiments may provide a connected standby sleep state to maintain processor context using a dedicated power plane. In one embodiment, the connected standby sleep state facilitates processor wakeup using resources of a PCH which itself may be present in a package with the processor. In one embodiment, the connected standby sleep state facilitates sustaining processor architectural functions in the PCH until processor wakeup, this enabling turning off all of the unnecessary processor components that were previously left powered on during deep sleep states, including turning off all of the clocks. In one embodiment, the PCH contains a time stamp counter (TSC) and connected standby logic for controlling the system during the connected standby state. The integrated voltage regulator for the sustain power plane may reside on the PCH as well.

In an embodiment, during the connected standby state, an integrated voltage regulator may function as a dedicated power plane that remains powered on to support the dedicated cache memory in which the processor context is stored such as critical state variables when the processor enters the deep sleep states and connected standby state. This critical state may include state variables associated with the architectural, micro-architectural, debug state, and/or similar state variables associated with the processor.

The wakeup source signals from EC 1135 may be sent to the PCH instead of the processor during the connected standby state so that the PCH can manage the wakeup processing instead of the processor. In addition, the TSC is maintained in the PCH to facilitate sustaining processor architectural functions. Although shown with these particular components in the embodiment of FIG. 11, understand the scope of the present techniques is not limited in this regard.

Power control in the processor can lead to enhanced power savings. For example, power can be dynamically allocate between cores, individual cores can change frequency/voltage, and multiple deep low power states can be provided to enable very low power consumption. In addition, dynamic control of the cores or independent core portions can provide for reduced power consumption by powering off components when they are not being used.

Some implementations may provide a specific power management IC (PMIC) to control platform power. Using this solution, a system may see very low (e.g., less than 5%) battery degradation over an extended duration (e.g., 16 hours) when in a given standby state, such as when in a Win8 Connected Standby state. In a Win8 idle state a battery life exceeding, e.g., 9 hours may be realized (e.g., at 150 nits). As to video playback, a long battery life can be realized, e.g., full HD video playback can occur for a minimum of 8 hours. A platform in one implementation may have an energy capacity of, e.g., 35 watt hours (Whr) for a Win8 CS using an SSD and (e.g.,) 40-44 Whr for Win8 CS using an HDD with a RST cache configuration.

A particular implementation may provide support for 15 W nominal CPU thermal design power (TDP), with a configurable CPU TDP of up to approximately 25 W TDP design point. The platform may include minimal vents owing to the thermal features described above. In addition, the platform is pillow-friendly (in that no hot air is blowing at the user). Different maximum temperature points can be realized depending on the chassis material. In one implementation of a plastic chassis (at least having to lid or base portion of plastic), the maximum operating temperature can be 52 degrees Celsius (C). And for an implementation of a metal chassis, the maximum operating temperature can be 46° C.

In different implementations, a security module such as a TPM can be integrated into a processor or can be a discrete device such as a TPM 2.0 device. With an integrated security module, also referred to as Platform Trust Technology (PTT), BIOS/firmware can be enabled to expose certain hardware features for certain security features, including secure instructions, secure boot, Intel® Anti-Theft Technology, Intel® Identity Protection Technology, Intel® Trusted Execution Technology (TXT), and Intel® Manageability Engine Technology along with secure user interfaces such as a secure keyboard and display.

### Example 1

A press-fit cable is described herein. The press-fit cable includes a plurality of cable wires and a plurality of pins. The plurality of pins are coupled with the plurality of cable wires and the plurality of pins is to directly mate to a circuit board without a receptacle.

The plurality of pins may be a plurality of press-fit pins. The plurality of press-fit pins may be separated by no more than 1.5 millimeters. Moreover, the plurality of pins may be eye-of-needle pins. Each pin of the plurality of pins may include an alignment notch. The plurality of pins may include a header surrounding the plurality of pins. The circuit board may include a plurality of vias to receive the plurality of pins when the plurality of pins is to directly mate to the circuit board. The press-fit cable may have a data transfer rate of at least 10 Gb/s. The plurality of pins may transfer data according to a Universal Serial Bus 3.1 protocol. Further, the circuit board may be a mother board.

### Example 2

An apparatus is described herein. The apparatus includes a circuit board and a press-fit cable. The press-fit cable is coupled directly to the circuit board without a receptacle, and the press-fit cable includes a plurality of cable wires and a plurality of pins.

The circuit board may include a plurality of vias to coupled with the plurality of pins, wherein a pitch of the plurality of vias is less than or equal to 1.5 millimeters. The plurality of cable wires may be coupled with the plurality of pins. The circuit board may be a motherboard of a server. The circuit board may also be a motherboard of a personal computer. The press-fit cable may have a data transfer rate of at least 10 Gb/s. Data may be transferred according to a Universal Serial Bus 3.1 protocol. Further, data may be transferred according to a Peripheral Component Interconnect Express (PCI-E) protocol. Impedance discontinuity and crosstalk may be mitigated by eliminating the receptacle. Additionally, the press-fit cable may enable high speed operation.

### Example 3

A system is described herein. The system includes a display, a radio, and an internal cable. The internal cable is connected to a motherboard of the system via a plurality of press-fit pins. The system also includes a memory that is to store instructions and that is communicatively coupled to the display, and a processor communicatively coupled to the radio and the memory.

The mother board includes a plurality of vias that may couple with the plurality of pins, wherein a pitch of the plurality of vias is less than or equal to 1.5 millimeters. A plurality of cable wires may couple with the plurality press-fit of pins. The system may include a data transfer rate of at least 10 Gb/s. Data transfer may be according to a Universal Serial Bus 3.1 protocol. Also, data transfer may be according to a PCI-E protocol. Additionally, impedance discontinuity and crosstalk may be mitigated by eliminating a receptacle on the motherboard. The plurality of pins may be eye-of-needle pins. Further, each pin of the plurality of pins may include an alignment notch. The processor communicatively may be coupled to the memory via the internal cable.

### Example 4

A method for receiving a press-fit cable at a circuit board is described herein. The method includes receiving a plurality of pins by a plurality of vias and securing the plurality of pins to the plurality of vias.

The plurality of pins may be secured to the plurality of vias automatically when the plurality of pints are received at the plurality of vias. Each pin of the plurality of pins may be notched to enable the pins to lock in place when received by the plurality of vias. Additionally, the plurality of pins may be eye-of-needle pins that are automatically secured when mated to the plurality of vias. The press-fit cable may have a data transfer rate of at least 10 Gb/s. A pitch of the plurality of vias may be less than or equal to 1.5 millimeters. The configuration of the press-fit cable may mitigate impedance discontinuity and crosstalk during data transfer. The press-fit cable may transfer data according to a Universal Serial Bus 3.1 protocol. Moreover, the press-fit cable may transfer data according to a Peripheral Component Interconnect Express (PCI-E) protocol. The press-fit cable may be an internal cable.

### Example 5

An apparatus is described herein. The apparatus includes a circuit board and a means to couple directly to the circuit board without a receptacle. The means to couple directly to the circuit board includes a plurality of cable wires and a plurality of pins.

The circuit board includes a plurality of vias that may coupled with the plurality of pins, wherein a pitch of the plurality of vias is less than or equal to 4.5 millimeters. The plurality of cable wires may couple with the plurality of pins. The circuit board may be a motherboard of a server. Additionally, the circuit board may be a motherboard of a personal computer. The apparatus may have a data transfer rate of at least 10 Gb/s. The apparatus may transfer data according to a Universal Serial Bus 3.1 protocol. Also, the apparatus may transfer data according to a Peripheral Component Interconnect Express (PCI-E) protocol. An impedance discontinuity and crosstalk may be mitigated by eliminating the receptacle. The means to couple directly to the circuit board may enable high speed operation.

While the present invention has been described with respect to a limited number of embodiments, those skilled in the art will appreciate numerous modifications and variations therefrom. It is intended that the appended claims cover all such modifications and variations as fall within the true spirit and scope of this present invention.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present invention.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘to’ or ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc, which are to be distinguished from the non-transitory mediums that may receive information there from.

Instructions used to program logic to perform embodiments of the invention may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the invention as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

What is claimed is:

1. A press-fit cable, comprising:
a plurality of cable wires; and
a plurality of pins, wherein the plurality of pins is coupled with the plurality of cable wires and the plurality of pins is to directly mate to a circuit board without a receptacle.

2. The press-fit cable of claim 1, wherein the plurality of pins is a plurality of press-fit pins.

3. The press-fit cable of claim 2, wherein the plurality of press-fit pins are separated by no more than 1.5 millimeters.

4. The press-fit cable of claim 1, wherein the plurality of pins are compliant pins, eye-of-needle pins, or any combination thereof.

5. The press-fit cable of claim 1, wherein each pin of the plurality of pins includes an alignment notch.

6. The press-fit cable of claim 1, comprising a protective header surrounding the plurality of pins.

7. The press-fit cable of claim 1, wherein the circuit board includes a plurality of vias to receive the plurality of pins when the plurality of pins is to directly mate to the circuit board.

8. An apparatus, comprising:
a circuit board; and
a press-fit cable coupled directly to the circuit board without a receptacle, wherein the press-fit cable includes a plurality of cable wires and a plurality of pins.

9. The apparatus of claim 8, wherein the circuit board includes a plurality of vias to be coupled with the plurality of pins, wherein a pitch of the plurality of vias is less than or equal to 1.5 millimeters.

10. The apparatus of claim 8, wherein the plurality of cable wires is coupled with the plurality of pins.

11. The apparatus of claim 8, wherein circuit board is a motherboard of a server.

12. The apparatus of claim 8, wherein circuit board is a motherboard of a personal computer.

13. The apparatus of claim 8, comprising a data transfer rate of at least 10 Gb/s.

14. The apparatus of claim 8, comprising data transfer according to a Universal Serial Bus 3.1 protocol.

15. The apparatus of claim 8, wherein the data transfer is based on a Universal Serial Bus Specification.

16. A system, comprising:
a display;
a radio;
an internal cable, wherein the internal cable is connected to a motherboard of the system via a plurality of press-fit pins;
a memory that is to store instructions and that is communicatively coupled to the display; and
a processor communicatively coupled to the radio and the memory.

17. The system of claim 16, wherein the mother board includes a plurality of vias to be coupled with the plurality of pins, wherein a pitch of the plurality of vias is less than or equal to 1.5 millimeters.

18. The system of claim 16, wherein a plurality of cable wires is coupled with the plurality press-fit of pins.

19. The system of claim 16, comprising a data transfer rate of at least 10 Gb/s.

20. The system of claim 16, comprising data transfer according to a Universal Serial Bus 3.1 protocol.

21. The system of claim 16, comprising data transfer according to a PCI-E protocol.

22. The system of claim 16, wherein data transfer is based on a Universal Serial Bus Specification.
